(19) United States
(12) Patent Application Publication
(10) Pub. No.: US 2025/0301577 A1
(43) Pub. Date: Sep. 25, 2025

(54) CHEMICAL VAPOR DEPOSITION METHOD OF DEPOSITING IRIDIUM OXIDE ON NEURAL PROBE, PROVIDED ON FLEXIBLE PRINTED CIRCUIT BOARD, USING OZONE GAS

(71) Applicant: UIF (University Industry Foundation), Yonsei University, Seoul (KR)

(72) Inventors: Heonjin Choi, Seoul (KR); Daerl Park, Seoul (KR)

(21) Appl. No.: 19/076,180

(22) Filed: Mar. 11, 2025

(30) Foreign Application Priority Data
Mar. 20, 2024 (KR) 10-2024-0038190

(51) Int. Cl. H05K 3/14; C23C 16/40; C23C 16/44; H05K 1/03

(52) U.S. Cl. CPC H05K 3/146; C23C 16/40; C23C 16/4408; H05K 1/0393; H05K 2203/1338

(57) ABSTRACT

Disclosed is a chemical vapor deposition method of depositing iridium oxide on a neural probe, provided on a flexible printed circuit board, using ozone gas, the chemical vapor deposition method including: step S100 of introducing an iridium precursor into a reaction chamber (furnace) in which a printed circuit board having a neural probe provided thereon is placed, and purging the inside of the reaction chamber with an inert gas for a predetermined time; and step S200 of introducing ozone (O₃) gas and an inert gas into the reaction chamber, and reacting the iridium precursor with the ozone gas at a predetermined reaction temperature, thereby depositing iridium oxide (IrO₂) on the surface of the neural probe.

### CROSS-REFERENCE TO RELATED APPLICATION

This application claims the benefit of Korean Patent Application No. 10-2024-0038190 filed on Mar. 20, 2024, which is hereby incorporated by reference herein in its entirety.

### BACKGROUND

### 1. Technical Field

The present invention relates to a chemical vapor deposition method for depositing iridium oxide. More specifically, the present invention relates to a chemical vapor deposition method of depositing iridium oxide on a neural probe, provided on a flexible printed circuit board (FPCB), using ozone gas.

### 2. Description of the Related Art

Pseudo-capacitance refers to the capacity of a capacitor to store energy as an electrode, and is a significantly important factor for the electrochemical resistance value in (AC). As the pseudo-capacitance value alternating current increases, the electrochemical resistance value decreases, which is a considerably advantageous property for neural stimulation in a neural probe.

Since iridium oxide has a high pseudo-capacitance value, it is widely used as an electrode for an electrochemical catalyst.

Conventional technologies includes chemical vapor deposition (CVD), which involves depositing iridium oxide by reacting an iridium precursor with oxygen at a temperature ranging from 350 to 550° C.

However, the conventional chemical vapor deposition (CVD) method has the following problems:

First, there is a problem in that the reaction of the iridium precursor with oxygen at a temperature in the range of 350 to 550° C. is not a method for optimizing deposition in chemical vapor deposition, but is only a method for producing iridium oxide.

Second, there is a problem in that, since the reaction temperature range of 350 to 550° C. overlaps with the melting point range (247 to 395° C.) of polyimide (PI), a polymer material commonly used for flexible circuit boards (FPCBs) for neural probes, the flexible printed circuit board may expand or melt in the reaction temperature range.

### RELATED ART LITERATURE

Patent Document: Korean Patent Application Publication No. 10-2004-0067804 (published on Jul. 30, 2004)

### SUMMARY

A chemical vapor deposition method of depositing iridium oxide on a neural probe, provided on a flexible printed circuit board (FPCB), using ozone gas according to the present invention has the following objects:

A first object is to lower the reaction temperature for the deposition of iridium oxide through the reaction between an iridium precursor and ozone.

A second object is to ensure that the melting point of a flexible printed circuit board does not fall within the reaction temperature range.

A third object is to increase deposition efficiency by presenting deposition conditions in detail.

The problems to be solved by the present invention are not limited to those mentioned above, and other problems not mentioned will be clearly understood by those skilled in the art from the following description.

The present invention relates to a chemical vapor deposition method of depositing iridium oxide on a neural probe, provided on a flexible printed circuit board, using ozone gas, including: step S100 of introducing an iridium precursor into a reaction chamber (furnace) in which a printed circuit board having a neural probe provided thereon is placed, and purging the inside of the reaction chamber with an inert gas for a predetermined time; and step S200 of introducing ozone (O₃) gas and an inert gas into the reaction chamber, and reacting the iridium precursor with the ozone gas at a predetermined reaction temperature, thereby depositing iridium oxide (IrO₂) on the surface of the neural probe.

In the present invention, the printed circuit board in step S100 may be a flexible printed circuit board.

In the present invention, the flexible printed circuit board may be composed of a polymer.

In the present invention, the polymer may be polyimide (PI).

In the present invention, the inert gas in step S200 may be introduced at a flow rate of 100 to 500 sccm.

In the present invention, the ozone gas in step S200 may be introduced in an amount 1 to 10 times the amount of the iridium precursor introduced.

In the present invention, the reaction temperature in the reaction chamber in step S200 may range from 160 to 185° C.

In the present invention, the temperature in the reaction chamber in step S200 may be increased at a rate of 1 to 10° C./min.

In the present invention, the chemical vapor deposition method may further include, after step S200, step S300 of introducing an inert gas into the reaction chamber to remove residual ozone and wash the printed circuit board having iridium oxide deposited on the neural probe.

In the present invention, after step S300, the chemical vapor deposition method may further include, after step S300, step S400 of measuring an impedance change depending on a frequency change in order to check the electrochemical properties of iridium oxide deposited on the surface of the neural probe.

In the present invention, if an impedance value smaller than 1/10 times the initial impedance is measured as a result of measuring the impedance change in step S400, it may be determined to be suitable.

The present invention also relates to a flexible printed circuit board (FPCB) having a neural probe having iridium oxide deposited thereon, which is obtained by depositing iridium oxide on the surface of a neural probe, provided on a flexible printed circuit board (FPCB) placed in a reaction chamber, according to the above-described chemical vapor deposition method.

In the present invention, the flexible printed circuit board may be composed of a polymer, and the polymer may be polyimide (PI).

In the present invention, the inert gas may be introduced at a flow rate of 100 to 500 sccm.

In the present invention, the ozone gas may be introduced in an amount of 1 to 10 times the amount of the iridium precursor introduced.

In the present invention, the reaction temperature in the reaction chamber may range from 160 to 185° C.

In the present invention, the temperature in the reaction chamber may be increased at a rate of 1 to 10° C./min.

The chemical vapor deposition method of depositing iridium oxide on a neural probe, provided on a flexible printed circuit board, using ozone gas according to the present invention has the following advantages:

First, the reaction temperature for the deposition of iridium oxide is reduced through the reaction of the iridium precursor with ozone rather than oxygen.

Second, the reaction temperature range is below the melting point of the flexible printed circuit board, and thus, the expansion or melting of the flexible printed circuit board does not occur, thereby enabling nerve stimulation without functional damage.

Third, the deposition conditions, such as the amount of inert gas introduced, the hourly change rate of the temperature in the reaction chamber, and the ratio of the iridium precursor to ozone, are presented in detail, thereby increasing the deposition efficiency.

The advantages of the present invention are not limited to those mentioned above, and other advantages not mentioned will be clearly understood by those skilled in the art from the following description.

### BRIEF DESCRIPTION OF THE DRAWINGS

FIG. 1 is a flowchart showing steps S100 and S200 included as essential elements in a chemical vapor deposition method of depositing iridium oxide according to the present invention;

FIG. 2 is a flowchart further including step S300 added to the flowchart of FIG. 1;

FIG. 3 is a flowchart further including step S400 added to the flowchart of FIG. 2;

FIG. 4 schematically shows a method of depositing iridium oxide;

FIG. 5 shows optical microscope images and scanning electron microscope (SEM) images of deposited iridium oxide;

FIG. 6 shows material analysis data for iridium oxide;

FIG. 7 is a graph showing the change in impedance value before the deposition of iridium oxide;

FIG. 8 is a graph showing the change in impedance value after the deposition of iridium oxide; and

FIG. 9 is a graph illustrating the impedance values after depositing iridium oxide at different temperatures at 1 KHz.

### DETAILED DESCRIPTION

Hereinafter, embodiments of the present invention will be described with reference to the attached drawings so that those skilled in the art can easily implement the present invention. As can be easily understood by those skilled in the art, the embodiments to be described below may be modified in various forms without departing from the spirit and scope of the present invention. Wherever possible, identical or similar parts are denoted by the same reference numerals throughout the drawings.

The technical terms used herein are merely for the purpose of describing specific exemplary embodiments, and are not intended to limit the present invention. Singular expressions used herein include plural expressions unless they have definitely opposite meanings.

The terms “include” and/or “including” used in the present specification specify particular features, regions, integers, steps, operations, elements, and/or components, but do not exclude the presence or addition of other particular features, regions, integers, steps, operations, elements, components, and/or groups thereof.

All terms used in the present specification, including technical or scientific terms, have the same meanings as meanings which are generally understood by those skilled in the art. It shall be additionally construed that terms, which are defined in dictionaries, have meanings matching the related art document and currently disclosed contents, and the terms shall not be construed as ideal or excessively formal meanings unless clearly defined in the present specification.

Expressions relating to direction used in the present specification, such as expressions of front/back/left/right, expressions of up/down, and expressions of vertical/horizontal direction, may be interpreted with reference to the directions disclosed in the drawings.

Directional expressions used in the present specification, such as front/back/left/right expressions, up/down expressions, or longitudinal/transverse direction expressions, may be interpreted with reference to the directions disclosed in the drawings.

The present invention relates to a method for depositing iridium oxide (IrO₂), which may be applied to a flexible printed circuit board (FPCB) composed of a polymer rather than silicon. The iridium oxide deposition method proposed in the present invention uses ozone (O₃) instead of oxygen (O₂) used in a conventionally known method of reacting an iridium precursor with oxygen at a high temperature, thereby lowering the reaction enabling deposition on an FPCB composed of a polymer.

Deposited iridium oxide may significantly reduce the impedance of the neural probe provided on the flexible circuit board, and this property is significantly important for stimulation electrodes.

Therefore, the present invention may be used in the fabrication of a stimulation electrode that may be used in actual biomedical devices.

As the inert gas in the present invention, any substance may be used as long as it serves to remove substances that can cause additional reactions, such as oxygen and moisture contained in the atmosphere. For example, as a result of conducting experiments with not only argon gas but also nitrogen gas, it was confirmed that deposition was performed without a problem.

A general role of the inert gas is to suppress additional reactions that may occur at elevated temperatures rather than room temperature, and this role is included in all of steps S100, S200, and S300 according to the present invention.

More specifically, in steps S100 and S300, the inert gas plays a role of suppressing additional reactions by increasing the temperature and lowering the increased temperature. However, in step S200, in addition to suppressing additional reactions, the inert gas also plays a role of uniformly diffusing the vaporized iridium precursor by controlling the flow rate, thereby ensuring uniform deposition.

Hereinafter, the present invention will be described with reference to the drawings. For reference, the dimensions of structures in the drawings may be exaggerated to illustrate the features of the present invention. In this case, interpretation is preferably made in light of the overall content of the present specification.

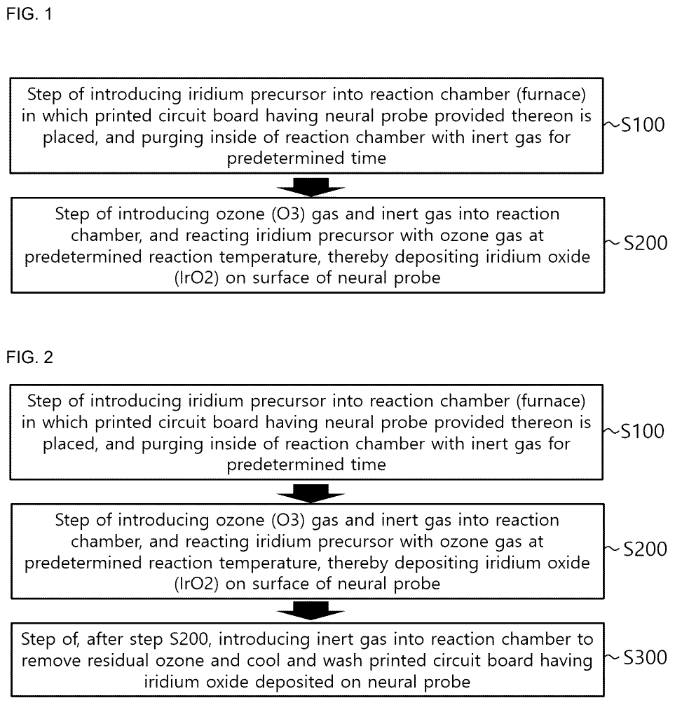

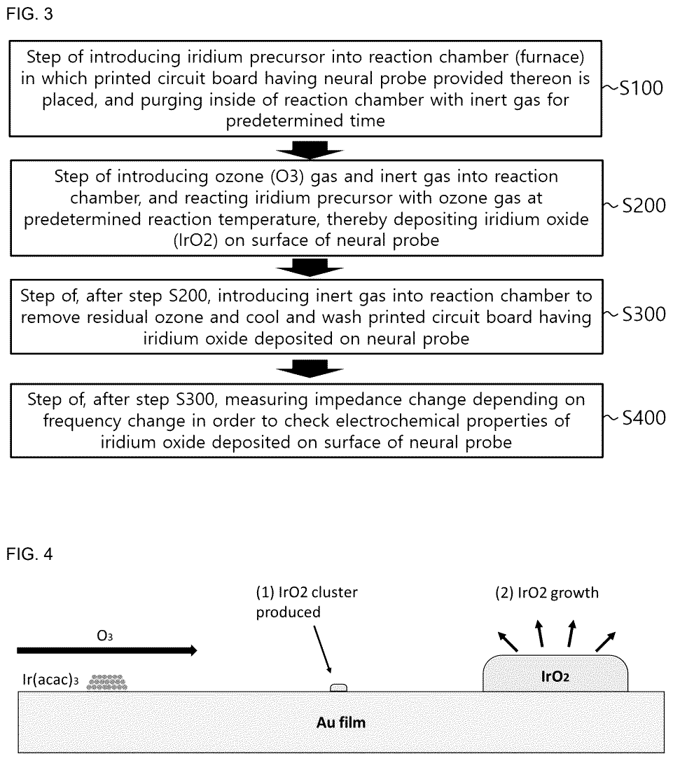

FIG. 1 is a flowchart showing steps S100 and S200 included as essential elements in a chemical vapor deposition method of depositing iridium oxide according to the present invention.

The present invention is directed to a chemical vapor deposition method of depositing iridium oxide on a neural probe, provided on a flexible printed circuit board, using ozone gas, the chemical vapor deposition method including: step S100 of introducing an iridium precursor into a reaction chamber (furnace) in which a printed circuit board having a neural probe provided thereon is placed, and purging the inside of the reaction chamber with an inert gas for a predetermined time; and step S200 of introducing ozone (O₃) gas and an inert gas into the reaction chamber, and reacting the iridium precursor with the ozone gas at a predetermined reaction temperature, thereby depositing iridium oxide (IrO₂) on the surface of the neural probe.

Hereinafter, step S100 according to the present invention will be described.

Step S100 according to the present invention may include introducing an iridium precursor into a reaction chamber (furnace) in which a printed circuit board having a neural probe provided thereon is placed, and purging the inside of the reaction chamber with an inert gas for a predetermined time

The printed circuit board in step S100 is preferably a flexible printed circuit board.

The flexible printed circuit board according to the present invention is preferably composed of a polymer. More preferably, the polymer is polyimide (PI). However, the material of the flexible printed circuit board is not limited to a specific material.

Meanwhile, as an example of a process of preparing step S100, a neural probe on a flexible printed circuit board, on which iridium oxide is to be deposited, is washed with distilled water, acetone, ethanol, etc., and then at least 10 mg of an iridium precursor represented by Ir(acac)₃ is prepared, and the neural probe may be positioned in the direction in which gas is introduced.

After inserting the prepared material into the reaction chamber (tube furnace), both ends may be sealed. After sealing, the inside of the reaction chamber is preferably purged with an inert gas such as argon gas for a predetermined time (5 minutes or more).

Step S200 according to the present invention will now be described.

Step S200 according to the present invention may include introducing ozone (O₃) gas and an inert gas into the reaction chamber, and reacting the iridium precursor with the ozone gas at a predetermined reaction temperature, thereby depositing iridium oxide (IrO₂) on the surface of the neural probe.

Step S200 is a step of controlling various conditions, such as the flow rate of inert gas that is introduced, the increase rate of the temperature in the reaction chamber, the flow rate of ozone compared to that of the precursor, and the reaction temperature in the reaction chamber, in order to deposit iridium oxide.

In step S200, the inert gas is preferably introduced at a flow rate of 100 to 500 sccm in order to prevent the inert gas from spreading rapidly as the iridium precursor temperature increases after purging with the inert gas.

If the flow rate of the inert gas that is introduced is less than 100 sccm, a problem may arise in that it is difficult for the iridium precursor to vaporize and diffuse sufficiently, and thus deposition is not easy and iridium oxide is formed at the position to which the iridium precursor is introduced. If the flow rate of the inert gas that is introduced is more than 500 sccm, a problem may arise in that the iridium precursor diffuses excessively quickly, and thus the material is deposited outside the reaction chamber rather than on the surface of the neural probe. That is, if the flow rate of the inert gas is out of the above range, a problem may arise in that no deposition occurs or deposition occurs in an unexpected location. Therefore, it is preferable that the flow rate of the inert gas that is introduced be 100 to 500 sccm.

In step S200, the ozone gas in step S200 is preferably introduced in an amount 1 to 10 times the amount of the iridium precursor introduced.

If the amount of the ozone gas is less than 1 times the amount of the iridium precursor introduced, a problem may arise in that it takes a long time to be deposited, and, if the amount of the ozone gas exceeds 10 times, a problem may arise in that the amount of ozone is excessively large, and thus, deposition is not easy. Therefore, the ozone gas in step S200 is preferably introduced in an amount 1 to 10 times the amount of the iridium precursor introduced.

In step S200, the reaction temperature in the reaction chamber in step S200 is preferably in the range of 160 to 185° C. The present invention is technically characterized by controlling the deposition temperature of iridium oxide so that a chemical vapor deposition (CVD) method may be used for a neural probe on a flexible printed circuit board composed of a polymer.

First, the upper limit of the reaction temperature may be set at 185° C. If the melting point of the polymer used as the material of the flexible printed circuit board or the temperature at which the properties of the polymer begin to change is lower than the upper limit of the reaction temperature, the desired electrical properties will not be realized.

Accordingly, in the case where the melting point range (247 to 395° C.) of polyimide (PI), which is a commonly used polymer, is taken into consideration, if the upper limit of the reaction temperature is adjusted to 185° C., iridium oxide with excellent electrical properties may be easily deposited at a temperature equal to or lower than the upper limit without damaging the flexible printed circuit board.

Next, the lower limit of the reaction temperature may be set at 160° C. A high temperature is required to deposit crystalline iridium oxide with excellent electrical properties by reacting the iridium precursor with ozone. If the reaction temperature is lowered, a problem arises in that the crystallinity of the iridium oxide decreases, and thus the electrical properties thereof tend to gradually decrease.

However, it was confirmed that, even when the lower limit of the reaction temperature was lowered to 160° C., iridium oxide, albeit amorphous, was deposited, and it was also confirmed that the required electrical properties were maintained even in the amorphous iridium oxide.

Accordingly, in the present invention, the reaction temperature in the reaction chamber is set to 160 to 185° C. and maintained for a predetermined time (e.g., at least 10 minutes) to cause the reaction.

In step S200, the temperature in the reaction chamber is preferably increased at a rate of 1 to 10° C./min. The reason for this is that, if the temperature in the reaction chamber is changed at an excessively high rate, only the surface temperature of the iridium precursor rises and the reaction occurs in that state, making it impossible to control the deposition thickness and reaction.

If the temperature rise rate is less than 1° C./min, there are no special problems in the reaction, but the reaction time is considerably long, and thus the temperature rise rate is set to 1° C./min or more. If the temperature rise rate exceeds 10° C./min, the temperature in the reaction chamber is recognized as sufficient for the reaction, but a problem arises in that the iridium precursor that must actually react in the reaction chamber does not have enough time to receive sufficient heat, and thus the reaction is insufficiently performed, so that deposition is not performed properly. Therefore, it is preferable that the temperature in the reaction chamber be increased at a rate of 1 to 10° C./min Step S300 according to the present invention will now be described.

Step S300 according to the present invention is performed after step S200 and may include introducing an inert gas into the reaction chamber to remove residual ozone and wash the flexible printed circuit board having iridium oxide deposited on the neural probe.

As an example, since ozone gas or unreacted iridium precursor may be physically adsorbed on the deposited iridium argon gas may be sufficiently flowed to remove 5 oxide, carcinogens such as ozone after the completion of the reaction, and the printed circuit board may be washed with water, ethanol, or the like.

Furthermore, it is also possible to cool the substrate at room temperature (about 20 to 30° C.).

Step S400 according to the present invention will now be described.

Step S400 according to the present invention is performed after step S300 and may include measuring an impedance change 5 depending on a frequency change in order to confirm the electrochemical properties of iridium oxide deposited on the surface of the neural probe.

If an impedance value smaller than 1/10 times the initial impedance is measured as a result of measuring the impedance change in step S400, it may be determined to be suitable.

Step S400 is a step of checking whether iridium oxide has been formed and its electrochemical properties. After the completion of the reaction, the formation of iridium oxide may also be checked using an optical microscope. Iridium oxide has a blue color. If the electrode has this color when observed through an optical microscope, it can be confirmed that iridium oxide has been deposited desirably.

If the reaction temperature is out of the range according to the present invention, the color change cannot be observed through an optical microscope, and thus it can be determined that iridium oxide has not been deposited properly.

In addition, in order to confirm the electrochemical properties of the deposited iridium oxide, an impedance change depending on a frequency change between about 100 and 10,000 Hz may be measured using a device capable of electrochemical impedance spectroscopy (EIS) analysis.

If the measurement results show that the impedance value is smaller than about 1/10 times the initial impedance, it may be determined to be ‘suitable’ as it means that iridium oxide has been deposited while maintaining desirable electrochemical properties.

The technical features of the present invention will further be described with reference to the drawings and data below.

FIG. 4 schematically shows a method of depositing iridium oxide. FIG. 4 is a schematic diagram illustrating the method of depositing iridium oxide, and schematically shows the order of the reaction between Ir(acac)₃ and ozone and the structure formed by the reaction.

As described above, by performing each step according to the present invention, it is possible to deposit iridium oxide on a neural probe on a flexible printed circuit board (FPCB).

In the present invention, iridium oxide may be deposited on a neural probe on any flexible printed circuit board in a period of time of, for example, about 60 minutes, and also the amount of iridium precursor for deposition, the temperature increase rate in the reaction chamber, and the amount of ozone generated are optimized.

These optimizations are significantly efficient for commercializing and mass-producing the neural probe of the present invention.

In the present invention, data may also be presented to confirm whether the iridium oxide has been properly deposited even through the modified method using ozone gas instead of oxygen gas and whether the impedance of the electrode has been properly reduced due to the high pseudo-capacitance of the iridium oxide.

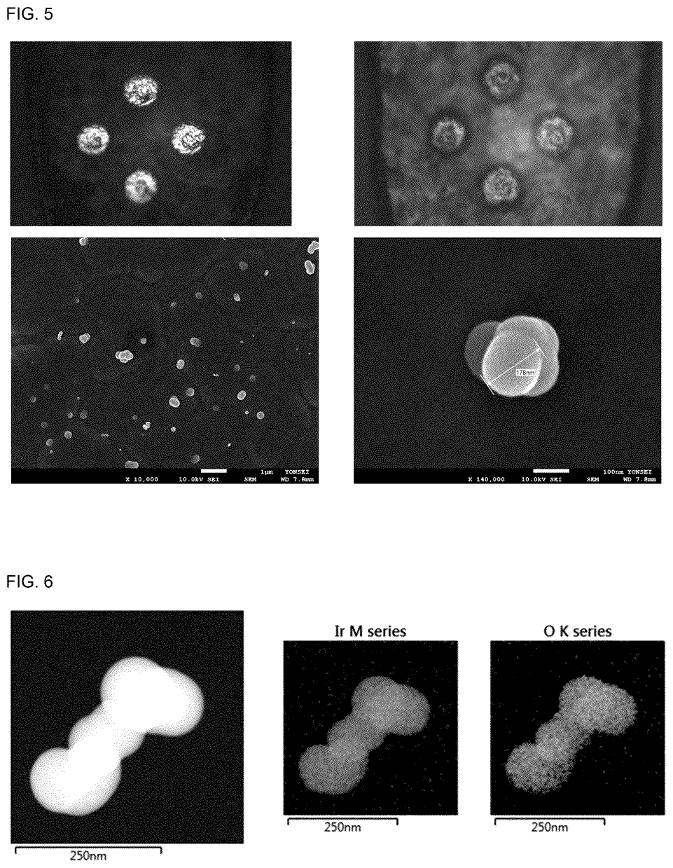

FIG. 5 shows optical microscope images and scanning electron microscope (SEM) images of deposited iridium oxide.

FIG. 5 depicts optical micrographs (OM) and scanning electron micrographs (SEM) showing nanoparticles deposited on an electrode by the method according to the present invention. The blue color can be confirmed on the electrode under an optical microscope, and the presence of nanoparticles on the surface can be confirmed under a scanning electron microscope. If the blue color is not confirmed on the surface under an optical microscope, it can be determined that the deposition was not done properly.

FIG. 6 shows material analysis data for iridium oxide. As material analysis data for nanoparticles obtained through the deposition method according to the present invention, the crystal structure was analyzed using transmission electron microscopy (TEM) and the material components were analyzed using energy dispersive spectroscopy (EDS). FIG. 6 is a high-magnification transmission electron microscope (TEM) image of the nanoparticles shown in in FIG. 5, and EDS mapping confirms that the particles are composed of iridium and oxygen, which proves that the synthesized material is iridium oxide.

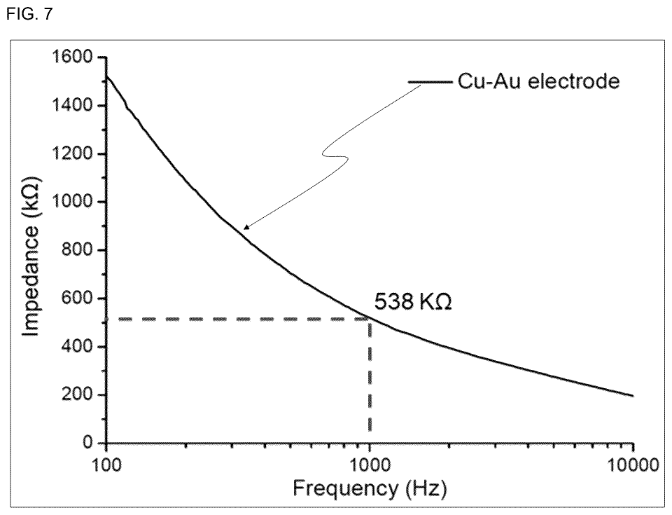

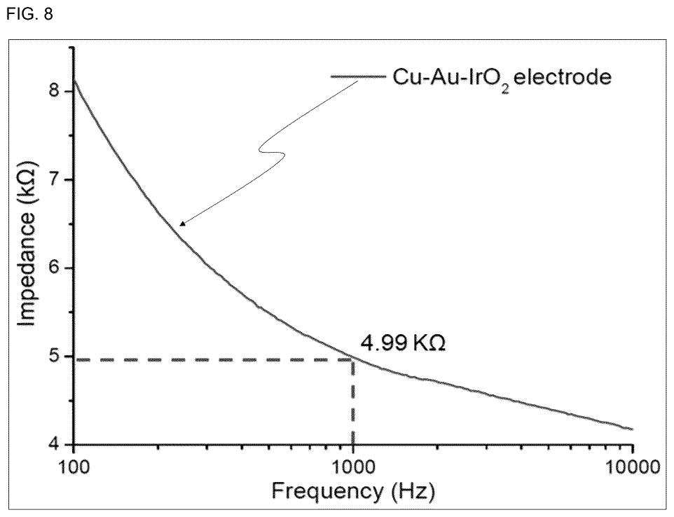

FIG. 7 is a graph showing the change in impedance value before the deposition of iridium oxide. FIG. 8 is a graph showing the change in impedance value after the deposition of iridium oxide.

FIGS. 7 and 8 show electrochemical impedance spectroscopy (EIS) analysis data that can confirm the impedance value with increasing frequency. As can be seen from the data, the impedance tends to decrease as the frequency increases. The most important value in EIS analysis is the impedance value at a frequency of 1 kHz. Referring to FIGS. 7 and 8, it can be seen that the sample without deposition has a resistance value of 538 KΩ (see FIG. 7), but when the resistance of the electrode after deposition at 175° C. is measured (see FIG. 8), it is 4.99 KΩ, which is almost 1/100 times the initial resistance value. This is a significantly useful property in the view that even a reduction in resistance of 1/10 or less is considered to be a significant reduction in impedance.

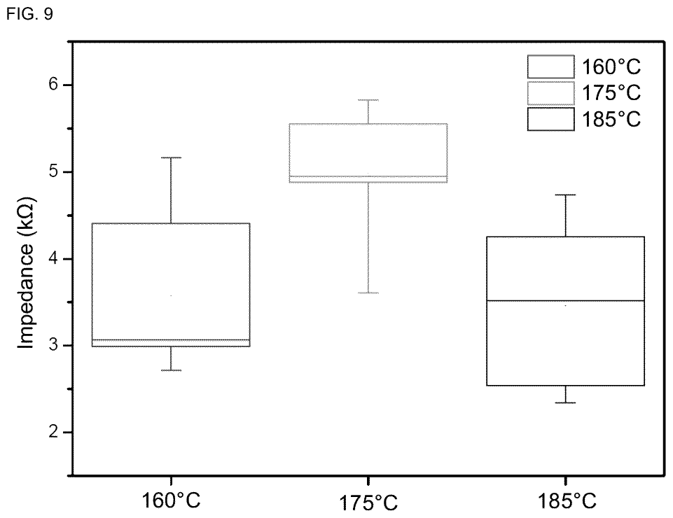

FIG. 9 is a graph illustrating the impedance values after depositing iridium oxide at different temperatures at 1 KHz. FIG. 9 is box plots showing impedance values at temperatures of 160° C., 175° C., and 185° C. in the reaction temperature range of 160 to 185° C. suggested in the present invention. A box plot is a graph that is displayed in the form of a box on the side where there are many data extracted within the maximum and minimum ranges.

Referring to the box plot at 160° C. in FIG. 9, it can be seen that the impedance values measured at 1 KHz are present in the range of 2.5 KΩ to 5.3 KΩ, and the average thereof corresponds to about 3.2 KΩ (the middle straight line of the box plot), and accordingly, there are more impedance values corresponding to the lower part.

Referring to the box plot at 175° C. in FIG. 9, it can be seen that the impedance values measured at 1 KHz are present in the range of 3.5 KΩ to 5.8 KΩ, and the average thereof corresponds to about 4.72 KΩ (the middle straight line of the box plot), and accordingly, there are more impedance values corresponding to the upper part.

Referring to the box plot at 185° C., it can be seen that the impedance values measured at 1 KHz are present in the range of 2.4 KΩ to 4.6 KΩ, and the average thereof is about 3.62 KΩ (the middle straight line of the box plot), and thus the impedance values are evenly distributed.

Overall, the range of the impedance appears to differ somewhat depending on the temperature, but due to the nature of the chemical vapor deposition method, it is not always possible to deposit uniformly, and there are slight differences each time an experiment is performed. However, as for the impedance values, the values are generally between 2 and 6 KΩ, which does not greatly deviate from the purpose of the present invention. In addition, even from the perspective of nerve stimulation to be applied in the future, they are sufficiently low impedance values, and thus, there is no problem at all and rather the error is considerably low.

It can be seen that the average impedances at the temperatures are 3.2 KΩ, 4.72 KΩ, and 3.62 KΩ, which slightly differ from one another, but the impedance values are generally between 2 KΩ and 6 KΩ.

FIG. 9 shows the impedance values at a frequency of 1 kHz at the lowest temperature of 160° C. and the highest temperature of 185° C., and it can be confirmed that these impedance values do not significantly differ from the impedance value at 175° C. shown in FIG. 8.

Based on these data, it can be confirmed that iridium oxide was formed desirably by the deposition method of the present invention as in the existing deposition method, and it can also be confirmed that the advantage in the electrochemical properties was also proved by the EIS analysis method.

In addition, it is proven that the present invention allows for mass production within a short time by a one-step process and performs deposition at a low temperature, and thus the deposition method of the present invention may be used even for a flexible printed circuit board composed of a polymer substrate, which is a key property of the present invention, indicating that the present invention may be used significantly advantageously in the application of flexible neural probes.

Meanwhile, the present invention may be implemented on a flexible printed circuit board having a neural probe. More specifically, the flexible printed circuit board having a neural according to the present invention may have iridium oxide deposited on the surface of the neural probe according to the chemical vapor deposition method of depositing iridium oxide using ozone gas according to the present invention.

The embodiments described herein and the accompanying drawings are merely illustrative of some of the technical spirit included in the present invention. Therefore, the embodiments disclosed herein are not intended to limit the technical spirit of the present invention but rather to describe the same, and thus, it is obvious that the scope of the technical spirit of the present invention is not limited by these embodiments. All modifications and specific embodiments that may be easily inferred by those skilled in the art within the scope of the technical spirit included in the specification and drawings of the present invention should be interpreted as being included in the scope of the present invention.

What is claimed is:

1. A chemical vapor deposition method of depositing iridium oxide on a neural probe, provided on a flexible printed circuit board, using ozone gas, the chemical vapor deposition method comprising:
step S100 of introducing an iridium precursor into a reaction chamber in which a printed circuit board having a neural probe provided thereon is placed, and purging an inside of the reaction chamber with an inert gas for a predetermined time; and
step S200 of introducing ozone (O₃) gas and an inert gas into the reaction chamber, and reacting the iridium precursor with the ozone gas at a predetermined reaction temperature, thereby depositing iridium oxide (IrO₂) on a surface of the neural probe.

2. The chemical vapor deposition method of claim 1, wherein the printed circuit board in step S100 is a flexible printed circuit board.

3. The chemical vapor deposition method of claim 2, wherein the flexible printed circuit board is composed of a polymer.

4. The chemical vapor deposition method of claim 3, wherein the polymer is polyimide (PI).

5. The chemical vapor deposition method of claim 1, wherein the inert gas in step S200 is introduced at a flow rate of 100 to 500 sccm.

6. The chemical vapor deposition method of claim 1, wherein the ozone gas in step S200 is introduced in an amount 1 to 10 times an amount of the iridium precursor introduced.

7. The chemical vapor deposition method of claim 1, wherein the reaction temperature in the reaction chamber in step S200 ranges from 160 to 185° C.

8. The chemical vapor deposition method of claim 7, wherein the temperature in the reaction chamber in step S200 is increased at a rate of 1 to 10° C./min.

9. The chemical vapor deposition method of claim 1, further comprising, after step S200, step S300 of introducing an inert gas into the reaction chamber to remove residual ozone and wash the printed circuit board having iridium oxide deposited on the neural probe.

10. The chemical vapor deposition method of claim 9, further comprising, after step S300, step S400 of measuring an impedance change depending on a frequency change in order to check the electrochemical properties of iridium oxide deposited on the surface of the neural probe.

11. The chemical vapor deposition method of claim 10, wherein, if an impedance value smaller than 1/10 times the initial impedance is measured as a result of measuring the impedance change in step S400, it is determined to be suitable.

12. A flexible printed circuit board having a neural probe having iridium oxide deposited thereon, which is obtained by depositing iridium oxide on a surface of a neural probe, provided on a flexible printed circuit board placed in a reaction chamber, according to the chemical vapor deposition method of claim 1.

13. The flexible printed circuit board of claim 12, wherein the flexible printed circuit board is composed of a polymer, and the polymer is polyimide (PI).

14. The flexible printed circuit board of claim 12, wherein the inert gas is introduced at a flow rate of 100 to 500 sccm.

15. The flexible printed circuit board of claim 12, wherein the ozone gas is introduced in an amount of 1 to 10 times an amount of the iridium precursor introduced.

16. The flexible printed circuit board of claim 12, wherein the reaction temperature in the reaction chamber ranges from 160 to 185° C.

17. The flexible printed circuit board of claim 12, wherein the temperature in the reaction chamber is increased at a rate of 1 to 10° C./min.
